(19) United States
(12) Patent Application Publication
(10) Pub. No.: US 2003/0047771 A1
(43) Pub. Date: Mar. 13, 2003

(54) Semiconductor device and method for fabricating the same

(76) Inventors: Soon-Yong Kweon, Ichon-shi (KR); Seung-Jin Yeom, Ichon-shi (KR)

Correspondence Address: BIRCH STEWART KOLASCH & BIRCH, PO BOX 747, FALLS CHURCH, VA, 22040-0747, US

(21) Appl. No.: 10/241,525

(22) Filed: Sep. 12, 2002

(30) Foreign Application Priority Data
Sep. 12, 2001 (KR) 2001-56144

(51) Int. Cl. H01L 27/108

(52) U.S. Cl. 257/306

(57) ABSTRACT

A semiconductor device includes a first insulating layer formed on a semiconductor substrate including a conductive layer. A plug passes through the first insulating layer and connects to the conductive layer in the semiconductor substrate. A barrier layer is formed on the plug. A second insulating layer is formed, through a planarization process, to be an equal height to that of the barrier layer on the first insulating layer. A capacitor is formed on the barrier layer.

### FIELD OF THE INVENTION

The present invention relates to a semiconductor device; and, more particularly, to a method for fabricating a semiconductor device capable of obtaining a stable process by protecting an oxidation of a bottom electrode of a capacitor.

### DESCRIPTION OF THE PRIOR ART

Recently, a ferroelectric material was developed as a dielectric material of a capacitor in a semiconductor memory device. The ferroelectric material overcame a limitation of a refresh cycle, which is necessary to a Dynamic Random Access Memory (DRAM), and was able to be used in the mass storage memory. A ferroelectric random access memory (FeRAM), in which a ferroelectric layer is used as a dielectric layer, is a nonvolatile semiconductor memory device with various characteristics of high integration of a DRAM, a speedy information process of a static random access memory (SRAM) and an information storing function of a flash memory.

SrBi₂Ta₂O₉ (hereinafter, referred to as SBT), Pb(Zr, Ti)O₃ (hereinafter, referred to as PBT) or the like is used as the dielectric material of the FeRAM. The ferroelectric materials have a high dielectric constant and two stable stats of remnant polarization so that the ferroelectric materials are applied to a capacitor of a nonvolatile memory device. The nonvolatile memory device using the ferroelectric layer has a hysteresis characteristic, which can represent digital signals ‘1’ and ‘0’ determined by a polarization direction, when an electric field is applied, and a remnant polarization direction, when the electric field is removed.

When the ferroelectric layer, such as SBT, PZT, SrₓBi_{y}(Ta₁Nbⱼ)₂O₉ (hereinafter, referred to as SBTN) or (Bi₄₋ₓ,Laₓ)Ti₃O₁₂ (hereinafter, referred to as BLT) layer, is used in the capacitor of the FeRAM device, top and bottom electrodes are generally formed by a metal layer, such as platinum (Pt), iridium (Ir), ruthenium (Ru), iridium oxide (IrOₓ), ruthenium oxide (RuOₓ) or Pt-alloy layer.

Now, a process according to the prior art for fabricating the capacitor of the FeRAM will be described. An interlayer insulating layer is formed on a semiconductor substrate including a source/drain junction and a gate electrode. Next, a contact plug, which passes through the interlayer insulating layer, is formed on the semiconductor substrate. The plug is usually formed with a polysilicon layer.

An Ohmic's layer or a barrier layer is formed on the plug with a TiN/TiSi₂ layer in order to reduce a contact resistance. A TiN layer is very weak for a thermal process in a high temperature, such as a thermal treatment for crystallization of the ferroelectric layer. Therefore, the TiN layer is buried in the interlayer insulating layer.

An IrO₂/Ir layer having a good diffusion barrier characteristic is used as a bottom electrode. When an Ir layer is used as the bottom electrode of the capacitor, the Ir layer contacts with the interlayer insulating layer, which is a SiO₂ layer. The Ir/SiO₂ interface has poor adhesion and it causes lifting between the Ir layer and the SiO₂ layers. As a result, an electrical characteristic is seriously deteriorated. Accordingly, a glue layer, such as an Al₂O₃ layer or the like, is formed between the Ir layer and the interlayer insulating layer to resist the lifting between the Ir layer and the SiO₂ layers.

FIG. 1 is a cross-sectional view showing a FeRAM, having a buried barrier structure using the glue layer as mentioned above. Referring to FIG. 1, a field oxide layer (Fox) 12 is locally formed on a semiconductor substrate 11. A source/drain 13, e.g. a doped region, is formed in the semiconductor substrate 11. An interlayer insulating layer 14 is formed on the semiconductor substrate 11 including the source/drain 13 and wordlines (not shown).

A plug 15 passes through the interlayer insulating layer 14 and contacts with the source/drain 13. A TiN layer 17 and TiSi₂ layer 16, provided as an Ohmic's layer and a barrier layer, are formed with a buried barrier structure on the plug 15.

A stacked bottom electrode having a Pt layer 21, a IrO₂ layer 20 and a Ir layer 19 is formed on the TiN layer 17 and a glue layer 18. The glue layer 18 is formed at a boundary between the Ir layer 19 and the interlayer insulating layer 14 by a Al₂O₃ layer or the like. A ferroelectric layer 22 is formed on the bottom electrode by a BLT layer, a SBT layer, a SBTN layer or the like. Then a top electrode 23 is formed.

After the glue layer 18 is deposited on the interlayer insulating layer 14 and the barrier layer 17, the top side of the barrier layer 17 has to be exposed to be connected with the bottom electrode. Therefore, a masking process is required.

Namely, after the TiN layer 17 is deposited on the entire structure, including the interlayer insulating layer 14 and the plug 15, the TiN layer 17 is polished by a chemical mechanical polishing (CMP) process, until the interlayer insulating layer 14 is exposed and the TiN layer 17 remains only in the contact hole. The Al₂O₃ layer is deposited, as the glue layer 18, on the interlayer insulating layer 14 and the TiN layer 17. Then, the glue layer 18 on the top side of the TiN layer 17 is selectively removed by using a masking process for opening the glue layer 18. Accordingly, the device manufacturing process is relatively complex and, when performing the masking process for opening the glue layer 18, a loss of the TiN layer 17 due to an over etching, and a loss of the glue layer 18 due to a lateral etch are caused.

The glue layer opening process is performed by a wet etching process or a dry etching process. When the dry etching process is applied, a topology of the surface of the TiN layer 17 is not good to form the bottom electrode, and the ferroelectric layer 22 because of the over etching. Therefore, a strength of a top portion of the contact region is deteriorated, and a void is generated. Accordingly, it is difficult to obtain desirable tolerances after the manufacturing process, and a device's characteristic performance is deteriorated.

When the wet etching process is applied to the glue layer 18, a process stability is deteriorated due to the over etching and the lateral etching. Namely, when the etching is not uniformly performed, a relatively thin thickness of the Ir layer 19 is generated so that a thermal stability of the device is deteriorated. Also, when the ferroelectric layer 22 is formed by a spin-on process, the electrical characteristic of the ferroelectric layer 22 is deteriorated according to the lower topology and this glue layer 18 open structure is hardly to be applied to a capacitor of a concave type.

The Prior art attempted to solve the above problems, by providing a structure, in which the Ir layer 19 is buried at the contact hole. FIG. 2 is a cross-sectional view showing a FeRAM attempting to solve the above problems.

In FIG. 2, a field oxide layer (Fox) 32 is locally formed on a semiconductor substrate 31 and a source/drain 33, e.g. a doped region is formed in the semiconductor substrate 31. A first interlayer insulating layer 34 is formed on the semiconductor substrate 31 including the source/drain 33 and wordlines (not shown). A plug 35 passes through the first interlayer insulating layer 34 and contacts with the source/drain 33. A TiN layer 37 and TiSi₂ layer 36, provided performed as an Ohmic's layer and a barrier layer, are formed as a type of a buried barrier structure on the plug 35.

A diffusion barrier layer 38, including Ir, is formed on the entire structure. Then, a planarization of the diffusion barrier layer 38 is performed, until the diffusion barrier layer 38 remains only in the contact hole. A second interlayer insulating layer 39 is formed on the entire structure and then selectively etched to expose a region including the diffusion barrier layer 38 and the TiN layer 37. A bottom electrode 40 is formed on the exposed region. Subsequently, a ferroelectric layer 41 and a top electrode 42 are formed.

As described above, the diffusion barrier layer 38 is buried in the contact hole, so that a formation of the glue layer is omitted. Also, the structure of the bottom electrode of the capacitor is simplified. Accordingly, the simplification of the etching process for a pattern formation of the bottom electrode 40 is expected, however, an Ir layer or a Ru layer needs a CMP process after deposition thereof.

It is very difficult to perform the CMP process for noble metals, such as Ir, Ru or the like, due to a physical characteristic thereof. Therefore, precise repeatability of a CVD technique and the CMP process is hard, and as a result the device's performance characteristic are reduced. Also, when the TiN layer 37 and the oxygen diffusion barrier layer 38 are stacked and buried in the contact hole, the above problems result.

### SUMMARY OF THE INVENTION

It is, therefore, an object of the present invention to provide a semiconductor device for protecting an oxidation of a bottom electrode thereby improving a stability and performance characteristic of the device, and an improved method for fabricating the device.

In accordance with an aspect of the present invention, there is provided a semiconductor device, comprising; a first insulating layer formed on a semiconductor substrate including a conductive layer; a plug passing through the first insulating layer and connected to the conductive layer of the semiconductor substrate; a barrier layer formed on the plug; a second insulating layer formed on the first insulating layer and formed to be an equal height to that of the barrier layer; and a capacitor formed on the barrier layer.

In accordance with another aspect of the present invention, there is provided a method for fabricating a semiconductor device, comprising the steps of: a) forming a first insulating layer on a semiconductor substrate including a conductive layer; b) forming a contact hole through the first insulating layer to expose the conductive layer of the semiconductor substrate; c) depositing a conductive material in the plug; d) performing a planarization process on at least the conductive material until the conductive material is a same height as the first insulating layer; e) forming a barrier layer connected to the plug; f) forming a second insulating layer on the first insulating layer and the barrier layer; g) performing a planarization process on the second insulating layer to expose a surface of the barrier layer; and h) forming a capacitor on the barrier layer.

Other objects and further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The above and other objects and features of the instant invention will become apparent from the following description of preferred embodiments taken in conjunction with the accompanying drawings, in which:

FIG. 1 is a cross-sectional view showing a FeRAM, having a buried barrier structure using a glue layer, according to the background art;

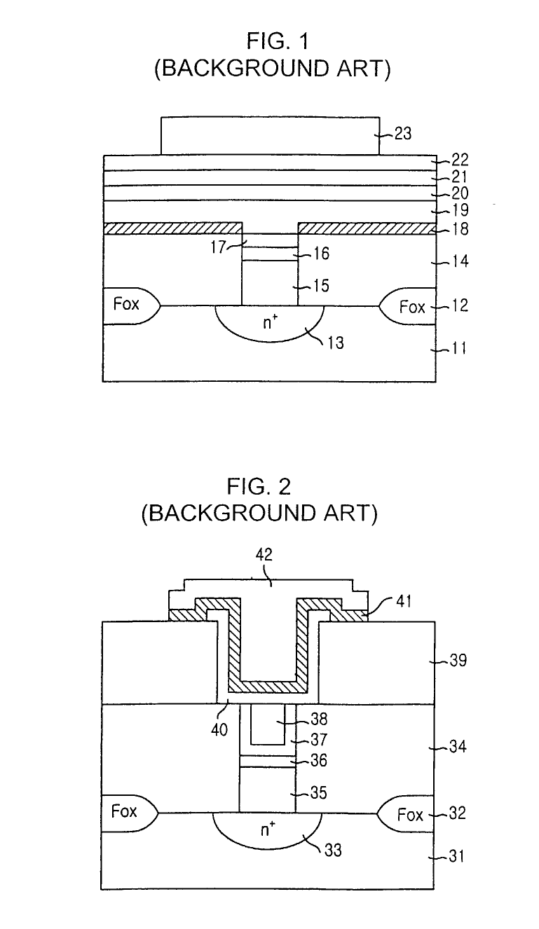

FIG. 2 a cross-sectional view showing a FeRAM improving the FeRAM in FIG. 1, according to the background art;

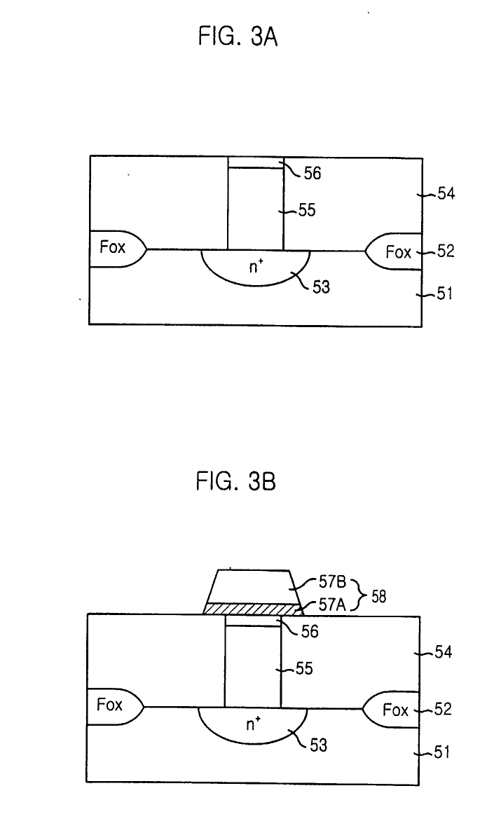

FIGS. 3A to 3D are cross-sectional views showing a process for fabricating a FeRAM, according to the present invention; and

FIG. 4 is a cross-sectional view showing a FeRAM applied to a capacitor of a concave type, according to the present invention.

### DETAILED DESCRIPTION OF THE PREFERRED EMBODIMENTS

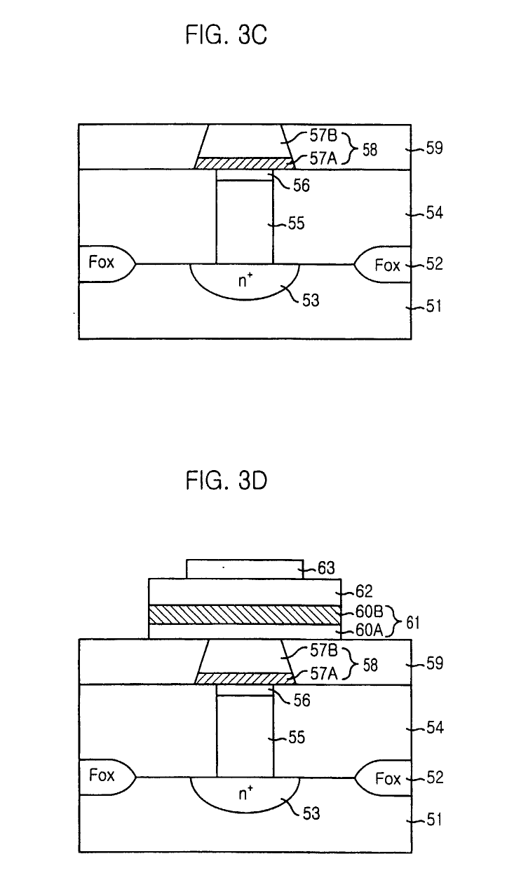

Hereinafter, a ferroelectric random access memory (FeRAM) according to the present invention will be described in detail, referring to the accompanying drawings. FIGS. 3A to 3D are cross-sectional views showing a method of fabricating a FeRAM according to the present invention.

Referring to FIG. 3A, a field oxide layer (Fox) 52 is formed on a semiconductor substrate 51 and a plurality of wordlines (not shown) are formed by depositing and patterning conductive materials, such as doped polysilicon and the like. A source/drain 53, e.g. a conductive layer, is formed at a portion of the semiconductor substrate 51 by an ion implanting process of dopants. A first interlayer insulating layer 54 is formed on the entire structure and then the first interlayer insulating layer 54 is selectively etched to expose a portion of the source/drain 53 so that a contact hole is formed.

The first interlayer insulating layer 54 is formed with a material selected from a group consisting of borosilicate glass (BSG), boro phospho silicate glass (BPSG), high density plasma oxide, undoped silicate glass (USG), tetra ethyl ortho silicate (TEOS), advanced planarization layer (APL) oxide, spin on glass (SOG), flowfill or combinations thereof.

A conductive material, such as polysilicon or the like, is deposited on the entire structure. Then, a planarization of the conductive material is performed until a height of the conductive material is equal to that of the first interlayer insulating layer 54. This forms a plug 55, which is buried in the contact hole. The recessed plug 55 is formed in the contact hole when an etching process for the planarization is performed with a different etching selection ratio between the conductive layer and the first interlayer insulating layer 54.

The plug 55 is formed with a material selected from a group consisting of doped polysilicon, tungsten (W), tungsten silicide, TiN, TiAlN, TaSiN, TiSiN, TaN, TaAlN, TiSi, TaSi and a combination thereof.

The conductive material is deposited by a technique selected from a group consisting of a chemical vapor deposition (CVD) technique, a physical vapor deposition (PVD) technique and an atomic layer deposition (ALD) technique.

Subsequently, a Ti layer is deposited on the entire structure and an etching process is performed. After the etching process, Ti remains only on the plug 55. A thermal treatment process is performed to cause a reaction between the polysilicon plug 55 and the Ti layer, so that a titanium silicide (TiSi) layer 56 is formed. The non-reacted Ti is removed by a wet etching process. The TiSi layer 56 is to play a role of an Ohmic's contact between the polysilicon plug 55 and a bottom electrode. The formation of the TiSi layer 56 may be omitted, and metal silicide, such as WSiₓ, MoSiₓ, CoSiₓ, NoSiₓ, TaSiₓ or the like, can be used instead of TiSi.

Referring to FIG. 3B, a diffusion barrier layer 58 is formed on the plug 55 at a thickness of approximately 50 Å to 5000 Å. The diffusion barrier layer 58 protects against an oxygen diffusion after the manufacturing process. It is preferable that the diffusion barrier layer 58 overlaps not only the plug 55 but also a portion of the interlayer insulating layer 54, near to the plug 55.

More particularly, a barrier metal layer 57A is formed on the plug 55 and a portion of the first interlayer insulating layer 54. The barrier metal layer 57A is selected from a group consisting of TiN, TiAlN, TaSiN, TiSiN, TaN, RuTiN and RuTiO. The barrier metal layer 57A is formed by a technique selected from a group consisting of a CVD technique, an ALD technique, an ionized metal plasma (IMP) technique, a collimation sputtering technique and a PVD technique.

The barrier metal layer 57A protects against metal is diffusing into the plug 55 and the semiconductor substrate 51 from metal layers, such as a capacitor electrode or the like. It is preferable to perform a N₂ or O₂ plasma treatment for improving a characteristic of the diffusion barrier.

The barrier layer 58 is a multiple layer structure, including the barrier metal layer 57A and an oxygen diffusion barrier layer 57B. The oxygen diffusion barrier layer 57B is formed with a material selected from a group consisting of Ir, Ru, Pt, Re, Ni, Co and Mo. The oxygen diffusion barrier layer 57B is formed on the barrier metal layer 57A by a technique selected from a group consisting of a CVD technique, a ALD technique, an IMP technique, a collimate sputtering technique and a PVD technique.

During a thermal treatment for crystallization of a dielectric layer of a capacitor, the oxygen diffusion barrier layer 57B protects against oxygen diffusing into the lower layers. It is preferable to perform a N₂ or O₂ plasma treatment. Also, a thermal treatment can be simultaneously carried out by using a diffusion furnace or a rapid thermal process (RTP). The thermal treatment is performed at an ambient of a N₂, O₂ or inert gas, such as a He, Ne, Ar or Xe gas, at a temperature of approximately 300° C. to 700° C. for 1 second to 5 hours.

Referring to FIG. 3C, a second interlayer insulating layer 59 is formed on the entire structure including the barrier layer 58. The second interlayer insulating layer 59 is formed at a thickness of approximately 500 Å to 5000 Å, enough to cover the barrier layer 58. The second interlayer insulating layer 59 is formed by a technique selected from a group consisting of the spin-on technique, the CVD technique, the PVD technique and the ALD technique. A planarization process of the second interlayer insulating layer 59 is performed until a height of the second interlayer insulating layer 59 is equal to that of the barrier layer 58.

As the second interlayer insulating layer 59 is polished or etched instead of the oxygen diffusion barrier layer 57B, which it is difficult to polish or etch, the stability and repeatability of the process can be guaranteed.

A thermal treatment process of the second interlayer insulating layer 59 is performed to improve the layer's performance characteristic and increase the layer's density. The thermal treatment can be carried out in a diffusion furnace or by RTP. The thermal treatment is performed at an ambient of a N₂, O₂ or inert gas, such as a He, Ne, Ar or Xe gas at a temperature of approximately 400° C. to 800° C. for approximately 1 second to 5 hours.

Referring to FIG. 3D, a first electrode 61 (60A and 60B), a dielectric layer 62 and a second electrode 63 are formed in this order on the oxygen diffusion barrier layer 57B.

Hereinafter, a process for forming a capacitor will be particularly described. The materials for the first electrode 61 are deposited on the entire structure with an ALD technique or the like. Then, a thermal treatment process is performed with a furnace thermal treatment or the RTP. The thermal treatment is carried out at an ambient of an O₂, O₃, N₂ or an Ar gas and at a temperature of approximately 200° C. to 800° C. Also, the thermal treatment is carried out for approximately ten minutes to five hours, in case the of the furnace thermal treatment, and for approximately 1 second to ten minutes in the case of the RTP. Also, a plasma treatment can be simultaneously carried out at an ambient of an O₂, O₃, N₂, N₂O or NH₃ gas.

The first electrode 61 is formed with two layers 60A and 60B, in a preferred embodiment of the present invention. Also, the first electrode can be formed with a plurality of metal layers or a single layer. Namely, the first electrode 61 can be formed with a material selected from a group consisting of Ir, IrOₓ (where, x is 1 to 2), PtOₓ (where, x is 0 to 1), Ru, RuOₓ (where, x is 1 to 2), Rh, RhOₓ (where, x is 1 to 2), Os, OsOₓ (x is 1 to 2), Pd, PdOₓ (where, x is 1 to 2), CaRuO₃, SrRuO₃, BaRuO₃, BaSrRuO₃, CaIrO₃, SrIrO₃, BaIrO₃, (La, Sr)CoO₃, Cu, Al, Ta, Mo, W, Au, Ag, Wsiₓ (where, x is 1 to 2), TiSiₓ (where, x is 1 to 2), MoSiₓ (where, x is 0.3 to 2), CoSiₓ (where, x is 0.5 to 1), NbSi, (where, x is 0.3 to 2), NiSi, (where, x is 0.5 to 2), TaSiₓ (where, x is 1 to 2), TiN, TaN, WN, TiSiN, TiAlN, TiBN, ZrSiN, ZrAlN, MoSiN, MoAlN, TaSiN, TaAlN and a combination thereof. A thickness of the first electrode 61 is approximately 50 Å to 5000 Å.

The dielectric layer 62 is formed on the first electrode 61 with a ferroelectric material or a high dielectric material, such as Ta₂O₅, SrTiO₃ (STO), BST, PZT, PLZT ((Pb, La) (Zr, Ti)O₃), BaTiO₃ (BTO), Pb(Mg_{1/3}Nb_{2/3})O₃) (PMN), (Sr, Bi) (Ta, Nb)₂O₉ (SBTN), (Sr, Bi)Ta₂O₉ (SBT), (Bi, La)Ti₃O₁₂ (BLT), BaTiO₃ (BT), SrTiO₃ (ST) or PbTiO₃ (PT). The dielectric layer 62 has a thickness of approximately 20 Å to 5000 Å and is formed by using a spin-on technique, a CVD technique, an ALD technique or a PVD technique.

A thermal treatment process, for crystallization of the dielectric layer 62 in order to improve a capacitance, is carried out at an ambient of a O₂, N₂, Ar, O₃, He, Ne or Kr gas and at a temperature of approximately 400° C. to 800° C. A diffusion furnace thermal treatment or a RTP may be used and the thermal treatment is carried out for approximately ten minutes to five hours. Subsequently, a second electrode 63 is formed on the dielectric layer 62 by using the same materials and deposition techniques for forming the first electrode 61.

The patterning process of the capacitor are separated into three steps. A first step is to pattern the second electrode 63. A second step is to pattern the dielectric layer 62. The last step is to pattern the first electrode 61. Also, the capacitor patterning process can be varied by simultaneously patterning the dielectric layer 62 and the first electrode 61, after patterning the second electrode 63.

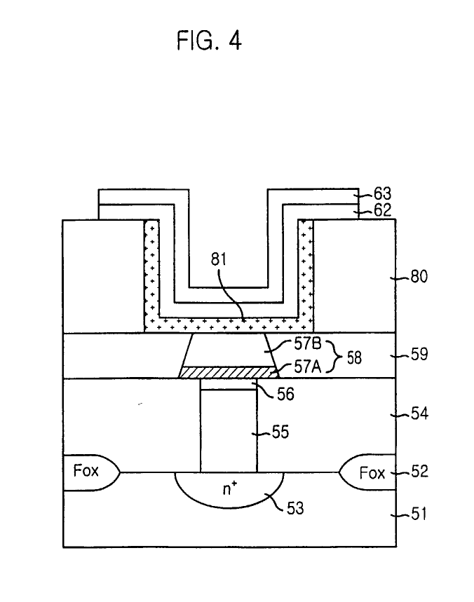

FIG. 4 is a cross-sectional view showing a FeRAM applied to a capacitor of a concave type, according to the present invention. The same reference numerals in FIGS. 3 and 4 denote the same elements.

Referring to FIG. 4, a capacitor of a concave type is shown. To form the capacitor of the concave type, a third interlayer insulating layer 80 is additionally formed on the second interlayer insulating layer 59. Also, a bottom electrode 81 is illustrated as a single layer for simplification of FIG. 4. The functions of other elements of FIG. 4 are the same as those of FIG. 3D, so that a detailed description of those elements will be omitted.

Accordingly, in accordance with the present invention, a process for forming the glue layer can be omitted, so that the process for fabricating a capacitor may be simplified. As the process for fabricating a semiconductor device is simplified, a fabricating cost can be reduced and a deterioration of the device can be protected against.

While the present invention has been described with respect to particular embodiments, it will be apparent to those skilled in the art that various changes and modifications may be made without departing from the spirit and scope of the invention as defined in the following claims.

What is claimed is:

1. A semiconductor device, comprising;
a first insulating layer formed on a semiconductor substrate including a conductive layer;
a plug passing through the first insulating layer and connected to the conductive layer of the semiconductor substrate;
a barrier layer formed on the plug;
a second insulating layer formed on the first insulating layer and formed to be an equal height to that of the barrier layer; and
a capacitor formed on the barrier layer.

2. The semiconductor device as recited in claim 1, wherein the barrier layer is buried in the second insulating layer.

3. The semiconductor device as recited in claim 1, wherein the barrier layer includes multiple stacked layers including a barrier metal layer and an oxygen diffusion barrier layer.

4. The semiconductor device as recited in claim 3, wherein the oxygen diffusion barrier layer is formed with a material selected from a group consisting of Tr, Ru, Pt, Re, Ni, Co, Mo, and a combination thereof.

5. The semiconductor device as recited in claim 3, wherein the barrier metal layer is formed with a material selected from a group consisting of TiN, TiAlN, TaSiN, TiSiN, TaN, RuTiN, RuTio, and a combination thereof.

6. The semiconductor device as recited in claim 1, wherein the barrier layer is formed at a thickness of approximately 50 Å to 5000 Å.

7. The semiconductor device as recited in claim 1, wherein the second insulating layer is initially formed on the first insulating layer at a thickness of approximately 500 Å to 5000 Å.

8. The semiconductor device as recited in claim 1, wherein the second insulating layer is formed with a material selected from a group consisting of an oxide layer, a nitride layer, an oxide-nitride layer, and a combination thereof.

9. The semiconductor device as recited in claim 1, wherein the capacitor includes a first electrode, a dielectric layer and a second electrode and the structure of the capacitor is a stacked type or a concave type.

10. The semiconductor device as recited in claim 9, wherein the first electrode is formed with a material selected from a group consisting of Ir, IrOₓ (where, x is 1 to 2), PtOₓ (where, x is 0 to 1), Ru, RuOₓ (where, x is 1 to 2), Rh, RhO, (where, x is 1 to 2), Os, OsOₓ (where, x is 1 to 2), Pd, PdOₓ (where, x is 1 to 2), CaRuO₃, SrRuO₃, BaRuO₃, BaSrRuO₃, CaIrO₃, SrIrO₃, BaIrO₃, (La, Sr) CoO₃, Cu, Al, Ta, Mo, W, Au, Ag, WSiₓ (where, x is 1 to 2), TiSiₓ (where, x is 1 to 2), MoSiₓ (where, x is 0.3 to 2), CoSiₓ (where, x is 0.5 to 1), NbSiₓ (where, x is 0.3 to 2), NiSiₓ (where, x is 0.5 to 2), TaSiₓ (where, x is 1 to 2), TiN, TaN, WN, TiSiN, TiAlN, TiBN, ZrSiN, ZrAlN, MoSiN, MoAlN, TaSiN, TaAlN, and a combination thereof.

11. The semiconductor device as recited in claim 9, wherein the dielectric layer includes a ferroelectric layer.

12. The semiconductor device as recited in claim 1, wherein the plug is formed with a material selected from a group consisting of polysilicon, tungsten (W), tungsten silicide, TiN, TiAlN, TaSiN, TiSiN, TaN, TaAlN, TiSi, TaSi, and a combination thereof.

13. The semiconductor device as recited in claim 1, wherein the semiconductor device further comprises an Ohmic's contact layer formed between the plug and the barrier layer and formed with a material selected from a group consisting of WSiₓ, TiSiₓ, MoSiₓ, CoSiₓ, NoSiₓ, TaSiₓ, and a combination thereof.

14. A method for fabricating a semiconductor device, comprising the steps of:
a) forming a first insulating layer on a semiconductor substrate including a conductive layer;
b) forming a contact hole through the first insulating layer to expose the conductive layer of the semiconductor substrate;
c) depositing a conductive material in the plug;
d) performing a planarization process on at least the conductive material until the conductive material is a same height as the first insulating layer;
e) forming a barrier layer connected to the plug;
f) forming a second insulating layer on the first insulating layer and the barrier layer;
g) performing a planarization process on the second insulating layer to expose a surface of the barrier layer; and
h) forming a capacitor on the barrier layer.

15. The method as recited in claim 14, wherein the step (e) comprises the steps of:
e1) depositing a barrier material on the plug and the first insulating layer; and
e2) selectively etching the barrier material.

16. The method as recited in claim 14, wherein the step (g) is performed by a chemical mechanical polishing process or a blanket etching process until the surface of the barrier layer is exposed.

17. The method as recited in claim 14, wherein the barrier layer is formed by stacking a barrier metal layer and an oxygen diffusion barrier layer.

18. The method as recited in claim 17, wherein the oxygen diffusion barrier layer includes a material selected from a group consisting of Ir, Ru, Pt, Re, Ni, Co, Mo, and a combination thereof.

19. The method for fabricating a semiconductor device as recited in claim 17, wherein the barrier metal layer is formed with a material selected from a group consisting of TiN, TiAlN, TaSiN, TiSiN, TaN, RuTiN, RuTio, and a combination thereof.

20. The method for fabricating a semiconductor device as recited in claim 14, wherein the barrier layer is formed at a thickness of approximately 50 Å to 5000 Å.

21. The method for fabricating a semiconductor device as recited in claim 14, wherein the second insulating layer is initially formed at a thickness of approximately 500 Å to 5000 Å.

22. The method for fabricating a semiconductor device as recited in claim 14, wherein the second insulating layer is formed with a layer selected from a group consisting of an oxide layer, a nitride layer, an oxide-nitride layer, and a combination thereof.

23. The method as recited in claim 14, wherein the step (b) includes selectively etching a portion of the first insulating layer to expose the conductive layer of the semiconductor substrate.

24. The method as recited in claim 14, wherein the step (c) also includes depositing the conductive material over the first insulating layer, and wherein the step (d) includes removing the conductive material from the first insulating layer during the planarization process.
